(19) United States
(12) Patent Application Publication
(10) Pub. No.: US 2011/0272783 A1
(43) Pub. Date: Nov. 10, 2011

(54) SEMICONDUCTOR DEVICE WITH BIPOLAR TRANSISTOR AND CAPACITOR

(75) Inventors: Wen Chin TSAY, Hsinchu City (TW); Wei-Chen LIANG, Hsinchu City (TW)

(73) Assignee: MIRACLE TECHNOLOGY CO., LTD., Hsinchu City (TW)

(21) Appl. No.: 13/090,347

(22) Filed: Apr. 20, 2011

(30) Foreign Application Priority Data
May 7, 2010 (TW) 099208509

(51) Int. Cl. H01L 29/92

(52) U.S. Cl. 257/532; 257/E29.342

(57) ABSTRACT

A semiconductor device with a bipolar transistor and a capacitor that has a down-sized circuit area is presented. During the manufacture of the bipolar transistor, a polysilicon-insulator-polysilicon capacitor, a polysilicon-insulator-metal layer or a metal-insulator-metal capacitor can be formed on the isolating insulator and/or the protective insulator to achieve reduced circuit area, less manufacturing steps and lowered manufacturing cost.

### FIELD OF THE INVENTION

The present invention generally relates to a semiconductor device with a bipolar transistor and a capacitor and, more particularly, to a semiconductor device that has a downsized circuit area.

### BACKGROUND OF THE INVENTION

The bipolar transistor has advantages such as high transconductance, low 1/f noise, constant Vbe voltage drop, high withstanding volate and current, high-speed switching, high gain and high current drivibility. Accordingly, the bipolar transistor has attracted tremendous attention in applications such as linear IC's, mixed-signal IC's and analog IC's.

However, the bipolar transistor based IC's are less integrated because the bipolar transistor occupies a larger area on the chip. The conventional IC with a bipolar transistor and a capacitor is as shown in FIG. 1. The IC 10 has an n-type epitaxial layer 14 formed on a p-type substrate 12, wherein a p-type buried layer 145 and an insulator 147 are then formed in the n-type epitaxial layer 14 and the p-type substrate 12 so as to isolate a plurality of device regions. In each device region, an n⁺-type buried layer 141 is provided between the n-type epitaxial layer 14 and the p-type substrate 12, and then device that is predetermined is formed in the device region. For example, in one device region, a collector region 161, a base region 163 and an emitter region 165 are provided to form a bipolar transistor. An protective insulator 149 is formed to cover the IC 10 and there are a collector contact 162, a base contact 164 and an emitter contact 166 provided through the protective insulator 149 to connect the collector region 161, the base region 163 and the emitter region 165, respectively. In another device region, a first electrode 181 is provided in the n-type epitaxial layer 14 and has the protective insulator 149 formed thereon. There is a second electrode 183 provided on the protective insulator 149 and a first electrode contact 185 provided through the protective insulator 149 to connect the first electrode 181 so as to form a capacitor.

Since the current of the bipolar transistor flows in the n-type epitaxial layer 14 and the first electrode 181 of the capacitor is embedded in the n-type epitaxial layer 14, the p-type buried layer 145 and the insulator 147 are required to isolate the devices to prevent interference. It results in large circuit area.

Moreover, since the protective insulator 149 is formed by oxidation in a furnace after a shallow n⁺-doped layer (as the first electrode 181) is formed on the n-type epitaxial layer 14, the capacitance of the capacitor is low because the oxide layer has to be thick enough for the heavily doped n⁺ ions.

### SUMMARY OF THE INVENTION

It is one object of the present invention to provide a semiconductor device with a bipolar transistor and a capacitor that has a downsized circuit area.

It is another object of the present invention to provide a semiconductor device with a bipolar transistor and a capacitor, wherein the capacitor is formed on an isolating insulator that isolates the transistors.

It is still another object of the present invention to provide a semiconductor device with a bipolar transistor and a capacitor, wherein the capacitor is a PIP capacitor, a PIM capacitor or a MIM capacitor.

It is still another object of the present invention to provide a semiconductor device with a bipolar transistor and a capacitor, wherein the conventional isolating insulator that isolates the transistors and the capacitors are not required, leading to a reduced circuit area.

The present invention provides a semiconductor device with a bipolar transistor and a capacitor, the semiconductor device comprising: a substrate; an epitaxial layer formed on the substrate; a plurality of isolating buried layers dividing the epitaxial layer into a plurality of device regions; a plurality of isolating insulators formed on the isolating buried layers, respectively; a plurality of bipolar transistors formed in the device regions, respectively; a protective insulator covering the device regions and the isolating insulators; and at least one capacitor formed on the protective insulator and corresponding to the isolating insulator.

The present invention further provides a semiconductor device with a bipolar transistor and a capacitor, the semiconductor device comprising: a substrate; an epitaxial layer formed on the substrate; a plurality of isolating buried layers dividing the epitaxial layer into a plurality of device regions; a plurality of isolating insulators formed on the isolating buried layers, respectively; a plurality of bipolar transistors formed in the device regions, respectively; a protective insulator covering the device regions and the isolating insulators; and at least one capacitor formed on the protective insulator and corresponding to an area excluding the bipolar transistor.

### BRIEF DESCRIPTION OF THE DRAWINGS

The objects and spirits of the embodiments of the present invention will be readily understood by the accompanying drawings and detailed descriptions, wherein:

FIG. 1 is a cross-sectional view of a conventional IC with a bipolar transistor and a capacitor;

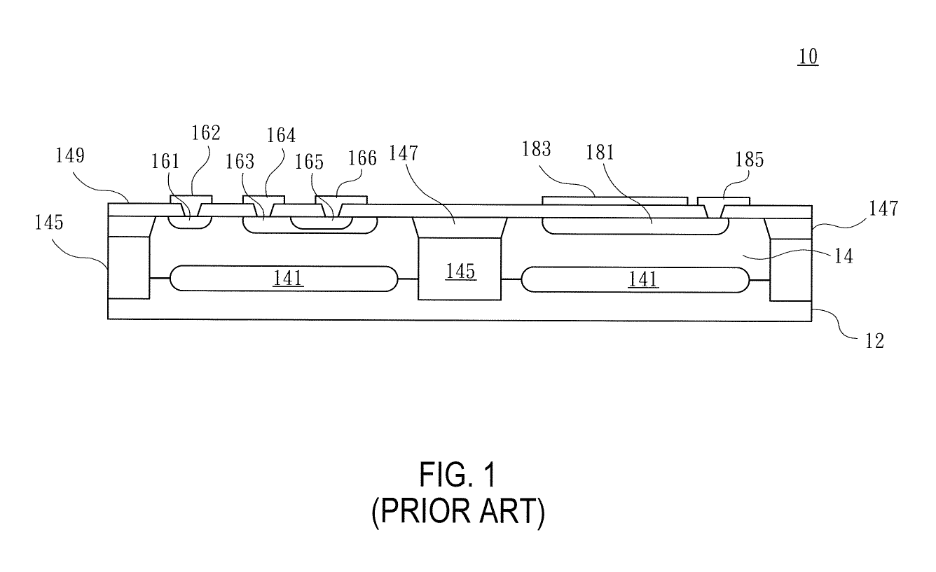

FIG. 2 is a cross-sectional view of a semiconductor device with a bipolar transistor and a capacitor according to one preferred embodiment of the present invention;

FIG. 3 is a cross-sectional view of a semiconductor device with a bipolar transistor and a capacitor according to another embodiment of the present invention; and

FIG. 4 is a cross-sectional view of a semiconductor device with a bipolar transistor and a capacitor according to still another embodiment of the present invention.

### DETAILED DESCRIPTION OF THE PREFERRED EMBODIMENT

The present invention can be exemplified but not limited by various embodiments as described hereinafter.

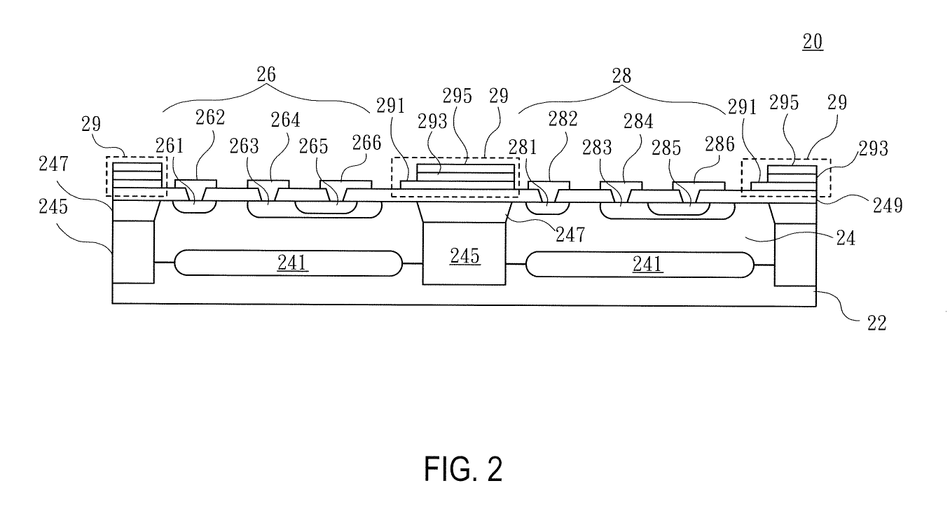

Please refer to FIG. 2, which is a cross-sectional view of a semiconductor device with a bipolar transistor and a capacitor according to one preferred embodiment of the present invention. In FIG. 2, the semiconductor device 20 comprises a substrate 22, an epitaxial layer 24 formed on the substrate 22, a plurality of isolating buried layers 245 dividing the epitaxial layer 24 into a plurality of device regions; and a plurality of isolating insulators 247 formed on the isolating buried layers 245, respectively.

There are a variety of transistors such as the first bipolar transistor 26 and the second bipolar transistor 28 formed in the device regions. A capacitor 29 may be formed on the isolating insulator 247.

Taking npn transistors for example, the substrate 22 is a p-type substrate, the epitaxial layer 24 is an n-type epitaxial layer, and the isolating buried layer 245 is a p-type buried layer. In each device region, an n⁺-type buried layer 241 is formed between the substrate 22 and the epitaxial layer 24. Furthermore, two n⁺-doped regions as the emitter region 265, 285 and the collector region 261, 281 and a p⁺-doped region as the base region 263, 283 are formed in the top portion of the epitaxial layer 24 of each device region 26, 28.

After a protective insulator 249 is deposited on each of the devices, a plurality of via holes are formed corresponding to the collector region 261, 281, the base region 263, 283 and the emitter region 265, 285. The via holes are then filled with polysilicon to form collector contacts 262, 282, base contacts 264, 284 and emitter contacts 266, 286.

During the formation of the contacts, a first electrode 291 is formed on the protective insulator 249 corresponding to the isolating insulator 247. Then, an insulator 293 and a second electrode 295 are deposited on the first electrode 291 in order. Consequently, a semiconductor device 20 with a bipolar transistor and a capacitor is completed.

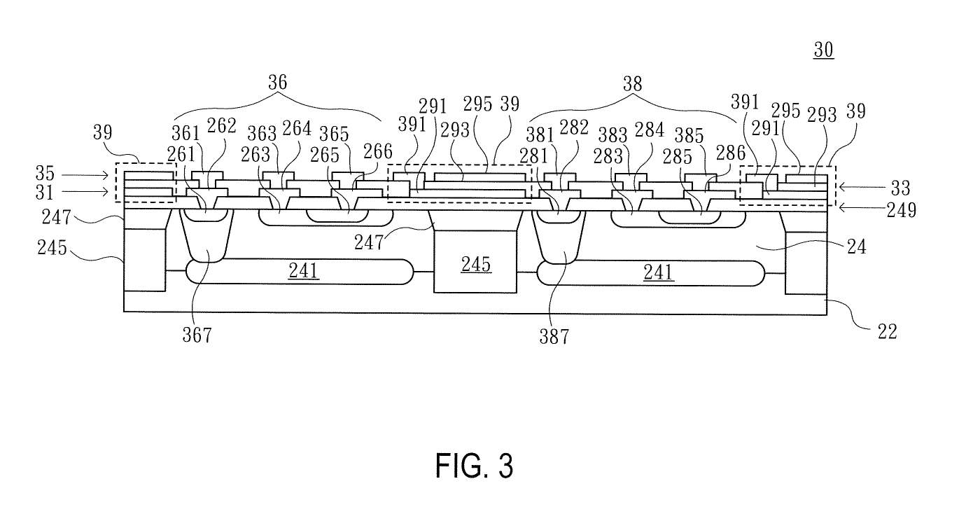

Please refer to FIG. 3, which is a cross-sectional view of a semiconductor device with a bipolar transistor and a capacitor according to another embodiment of the present invention. In FIG. 3, the semiconductor device 30 in the present embodiment is similar to the semiconductor device 20 in FIG. 2 except that the epitaxial layer 24 in FIG. 3 is further provided with n⁺-well regions 367, 387 to be connected to the collector regions 261, 281 and the n⁺-type buried layers 241. Consequently, the turn-on resistance of the transistors 36, 38 can be reduced.

Moreover, the manufacturing steps of the capacitor 39 can be combined with the manufacturing steps of the bipolar transistors 36, 38. For example, the first electrode 291 of the capacitor 39 is formed during the formation of the contacts of the bipolar transistors and deposited on the protective insulator 249 corresponding to the isolating insulator 247. The insulator 293 of the capacitor 39 is formed during the formation of the insulator 33 that covers the contacts. Moreover, the second electrode 295 of the capacitor 39 is a part of the patterned metal layer 35 of the semiconductor device 30 and thus is formed with the collector electrodes 361, 381, the base electrodes 363, 383, the emitter electrodes 365, 385 and the first electrode contact 391 at the same time.

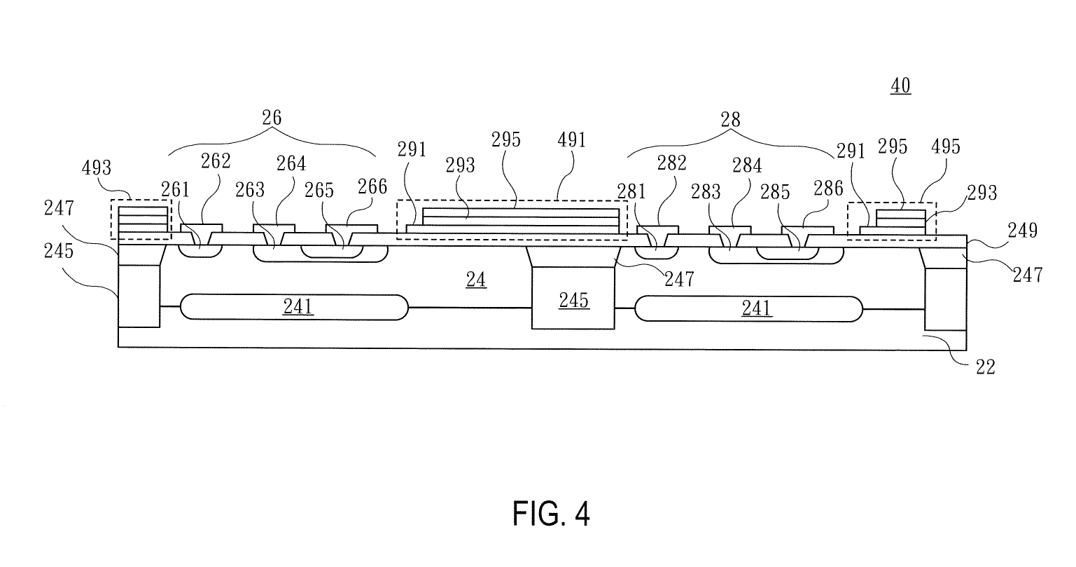

Please refer to FIG. 4, which is a cross-sectional view of a semiconductor device with a bipolar transistor and a capacitor according to still another embodiment of the present invention. In FIG. 4, the semiconductor device 40 in the present embodiment is similar to the semiconductor device 20 in FIG. 2 except that the capacitor in FIG. 4 is formed on the protective insulator 249 and corresponding to an area excluding the bipolar transistors 26, 28. For example, the capacitor 495 is formed between the bipolar transistor 28 and the isolating insulator 247; the capacitor 493 is formed on the isolating insulator 247; and the capacitor 491 is formed on an area excluding the bipolar transistors 26, 28.

In the semiconductor device of the present invention, the capacitor can be a polysilicon-insulator-polysilicon (PIP) capacitor, a polysilicon-insulator-metal (PIM) capacitor or a metal-insulator-metal (MIM) capacitor. The insulator of the capacitor can be an oxide layer (preferably, an silicon dioxide layer) to achieve low cost. Alternatively, the insulator of the capacitor can also be implemented using an oxide-nitride-oxide (ONO) layer to form a sandwiched structure for higher capacitance.

Accordingly, the present invention discloses a semiconductor device with reduced circuit area, less manufacturing steps and lowered manufacturing cost.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A semiconductor device with a bipolar transistor and a capacitor, the semiconductor device comprising:
a substrate;
an epitaxial layer formed on the substrate;
a plurality of isolating buried layers dividing the epitaxial layer into a plurality of device regions;
a plurality of isolating insulators formed on the isolating buried layers, respectively;
a plurality of bipolar transistors formed in the device regions, respectively;
a protective insulator covering the device regions and the isolating insulators; and
at least one capacitor formed on the protective insulator and corresponding to the isolating insulator.

2. The semiconductor device as recited in claim 1, wherein the capacitor is a polysilicon-insulator-polysilicon (PIP) capacitor.

3. The semiconductor device as recited in claim 1, wherein the capacitor is a polysilicon-insulator-metal (PIM) capacitor.

4. The semiconductor device as recited in claim 1, wherein the capacitor is a metal-insulator-metal (MIM) capacitor.

5. The semiconductor device as recited in claim 1, wherein the capacitor comprises an insulator formed of an oxide layer or an oxide-nitride-oxide (ONO) layer.

6. A semiconductor device with a bipolar transistor and a capacitor, the semiconductor device comprising:
a substrate;
an epitaxial layer formed on the substrate;
a plurality of isolating buried layers dividing the epitaxial layer into a plurality of device regions;
a plurality of isolating insulators formed on the isolating buried layers, respectively;
a plurality of bipolar transistors formed in the device regions, respectively;
a protective insulator covering the device regions and the isolating insulators; and
at least one capacitor formed on the protective insulator and corresponding to an area excluding the bipolar transistor.

7. The semiconductor device as recited in claim 6, wherein the capacitor is a polysilicon-insulator-polysilicon capacitor.

8. The semiconductor device as recited in claim 6, wherein the capacitor is a polysilicon-insulator-metal capacitor.

9. The semiconductor device as recited in claim 6, wherein the capacitor is a metal-insulator-metal capacitor.

10. The semiconductor device as recited in claim 6, wherein the capacitor comprises an insulator formed of an oxide layer or an oxide-nitride-oxide layer.
